(19) United States
(12) Patent Application Publication
(10) Pub. No.: US 2026/0059684 A1
(43) Pub. Date: Feb. 26, 2026

(54) PLUGGABLE REMOTE ACTUATOR MODULE AND ELECTRONIC DEVICE USING SAME

(71) Applicant: Delta Electronics, Inc., Taoyuan City (TW)

(72) Inventors: Chien-Chun Chen, Taoyuan City (TW); Shan-Chun Yang, Taoyuan City (TW); Mu-Bo Chang, Taoyuan City (TW); Tzu-Ching Chuang, Taoyuan City (TW)

(21) Appl. No.: 19/247,588

(22) Filed: Jun. 24, 2025

Related U.S. Application Data
(60) Provisional application No. 63/684,974, filed on Aug. 20, 2024.

(30) Foreign Application Priority Data
Nov. 11, 2024 (TW) 113143092

(51) Int. Cl. H05K 7/14; G08C 19/00

(52) U.S. Cl. CPC H05K 7/1452; G08C 19/00

(57) ABSTRACT

A pluggable remote actuator module and an electronic device are disclosed. The remote actuator module includes a base, a RAU, a pair of bullet terminals and a BMI male terminal. The RAU is disposed on the base. The bullet terminals are disposed adjacent to a front edge of the base, facing a first direction, and electrically connected to the RAU. The BMI male terminal is disposed adjacent to the front edge of the base, facing the first direction, located between the bullet terminals, and electrically connected to the RAU through a circuit board. When the pluggable remote actuator module is docked with a power-distribution-device base along the first direction, the bullet terminals are inserted into a pair of bullet slots on the power-distribution-device base and allow power connection, and the BMI male terminal is inserted into a BMI female terminal on the power-distribution-device base and allows signal connection.

### CROSS-REFERENCE TO RELATED APPLICATION

This application claims the benefit of U.S. Provisional Application No. 63/684,974 filed on Aug. 20, 2024, and entitled “PLUGGABLE REMOTE ACTUATOR MODULE AND INVISIBLE E-LOCK DOOR”. This application claims priority to Taiwan Patent Application No. 113143092, filed on Nov. 11, 2024. The entireties of the above-mentioned patent applications are incorporated herein by reference for all purposes.

### FIELD OF THE INVENTION

The present disclosure relates to an electronic device, and more particularly to a pluggable remote actuator module and an electronic device using the same, which has an electronic-device base and a remote actuator module through bullet terminals and blind mate interface (BMI) terminals, so as to achieve the connection/disconnection of power and signal at the same time during the process of plugging/unplugging the remote actuator module.

### BACKGROUND OF THE INVENTION

In view of the increasing use of “remote actuators” in communication power supplies, the telecommunications providers can easily remotely turn on/off the power supplies of their equipment by installing remote actuator units on electronic devices, and further monitor the power usage status. However, there are still many limitations in the structural design of the remote actuator modules. In particular, the complicated wiring connections make replacement inconvenient.

In conventional electronic devices, no matter what type of connection method is used to realize the power transmission of the remote actuator structure, the signal terminals and the auxiliary switch wiring need to be removed in advance when the remote actuator unit of the electronic device is replaced. This kind of architecture seems to be cumbersome in conventional miniaturized designs, and it also increases the time required for site maintenance.

Therefore, there is a need of providing a pluggable remote actuator module and an electronic device using the same, which has an electronic-device base and a remote actuator module through bullet terminals and blind mate interface (BMI) terminals, so as to achieve the connection/disconnection of power and signal at the same time during the process of plugging/unplugging the remote actuator module, and obviate the drawbacks encountered from the prior arts.

### SUMMARY OF THE INVENTION

It is an object of the present disclosure to provide a pluggable remote actuator module and an electronic device using the same. An electronic-device base includes a bullet slot for power transmission and a BMI female terminal for communication transmission. In addition, the remote actuator module includes a bullet terminal and a BMI male terminal capable of entering/leaving the electronic-device base at the same time, so that the connection/disconnection of power and signal is achieved at the same time during the process of plugging/unplugging the remote actuator module.

It is another object of the present disclosure to provide a pluggable remote actuator module and an electronic device using the same. The connection between the pluggable remote actuator module and the electronic-device base is realized through a modular design. The remote actuator module can be directly hot-swapped and replaced during site maintenance. In the present disclosure, the line bullet terminal and the load bullet terminal constructed corresponding to the line end and the load end of the remote actuator unit are protruded from a front edge of the base along the docking direction to facilitate docking with the bullet slot on the electronic device base. The line end and the load end are extended to the bullet terminals through metal conductors. The metal conductors can be fixed by insulated fixtures on the base, so as to provide the sufficient structural support at the same time. The fixtures and the base can also be integrally formed from plastic materials. Furthermore, the auxiliary contacts and the signal terminals of the remote actuator unit are integrated into a BMI male terminal through a circuit board, and it helps to increase the reliability of the communication connection when the remote actuator module is connected in the blindly plugging way. Preferably, the auxiliary contacts and the signal terminals are assembled to an integrated circuit board through crimp terminals, auxiliary circuits or clip components, or directly connected the integrated circuit board, and then connected to the BMI male terminal. In this way, the BMI male terminal can be arranged correspondingly between the pairs of bullet terminals, and corresponds to the bullet slots and the BMI female terminal on the electronic-device base to form an optimal alignment mechanism. Thereby, the docking process is simplified and the sufficient structural support is provided to prevent the bullet terminals and BMI terminals from being damaged during the plugging/unplugging process of the remote actuator module. On the other hand, in the modular manner of the present disclosure, it allows to simultaneously install a plurality of remote actuator modules on the base of a communication power supply device, and each remote actuator module can be taken out and replaced individually. The process of inserting or removing each remote actuator module into the electronic-device base requires only one plug/unplug action to complete the connection/disconnection of power and signals, so that the operating procedures are simplified effectively and the work efficiency is improved. The present disclosure includes the industrial applicability and the inventive steps.

In accordance with an aspect of the present disclosure, a pluggable remote actuator module is provided and includes a base, a remote actuator unit (RAU), a pair of bullet terminals and a blind mate interface (BMI) male terminal. The RAU is disposed on the base. The pair of bullet terminals are disposed adjacent to a front edge of the base, face a first direction, and are electrically connected to the RAU for transmitting power to and from the RAU. The BMI male terminal is disposed adjacent to the front edge of the base, faces the first direction, is located between the pair of bullet terminals, and is electrically connected to the RAU through at least one circuit board for transmitting signals to and from the RAU. When the pluggable remote actuator module is docked with a power-distribution-device base along the first direction, the pair of bullet terminals are inserted into a pair of bullet slots on the power-distribution-device base and allow power connection, and the BMI male terminal is inserted into a BMI female terminal on the power-distribution-device base and allows signal connection.

In an embodiment, the pair of bullet terminals includes a line bullet terminal and a load bullet terminal, which are protruded from the front edge of the base along the first direction.

In an embodiment, the RAU includes a line end, a load end and a front surface, the line end and the load end are disposed adjacent to an upper edge of the front surface, the line end is connected to the line bullet terminal through a line metal conductor, and the load end is connected to the load bullet terminal through a load metal conductor.

In an embodiment, the pluggable remote actuator module further includes a pair of fixtures. The pair of fixtures are disposed adjacent to two opposite ends of the front edge of the base, respectively, and connected between the front surface of the RAU and the front edge of the base, wherein the pair of fixtures are made of an insulating material, and configured to support the line metal conductor and the load metal conductor, and fix the line bullet terminal and the load bullet terminal.

In an embodiment, the line metal conductor and the load metal conductor are fastened on top surfaces of the pair of fixtures through screws, and the line bullet terminal and the load bullet terminal are fixed on front ends of the pair of fixtures.

In an embodiment, the base and the pair of fixtures are made of plastic materials and integrally formed into one piece.

In an embodiment, the at least one circuit board is an integrated circuit board fastened on the base, located between the pair of fixtures, and connected between the BMI male terminal and the front surface of the RAU.

In an embodiment, the RAU includes a signal terminal disposed adjacent to a lower edge of the front surface, spatially corresponding to the integrated circuit board and directly connected to the integrated circuit board.

In an embodiment, the RAU includes an auxiliary contact disposed adjacent to the upper edge of the front surface and located between the line end and the load end.

In an embodiment, the pluggable remote actuator module further includes a crimp terminal, wherein the auxiliary contact is connected to the integrated circuit board through the crimp terminal.

In an embodiment, the pluggable remote actuator module further includes an auxiliary circuit board and a clip component, wherein the auxiliary circuit board and the integrated circuit board are arranged in parallel and electrically connected to each other, and the clip component is arranged on an edge of the auxiliary circuit board, spatially corresponding to the auxiliary contact, and configured to clamp the auxiliary contact to form an electrical connection.

In accordance with another aspect of the present disclosure, an electronic device is provided and includes a power-distribution-device base and at least one pluggable remote actuator module. The power-distribution-device base includes a pair of bullet slots and a blind mate interface (BMI) female terminal. The pair of bullet slots and the BMI female terminal are arranged to face an identical direction. The at least one pluggable remote actuator module includes a base, a remote actuator unit (RAU), a pair of bullet terminals and a BMI male terminal. The RAU is disposed on the base. The pair of bullet terminals are disposed adjacent to a front edge of the base, face a first direction, and are electrically connected to the RAU for transmitting power to and from the RAU. The BMI male terminal is disposed adjacent to the front edge of the base, faces the first direction, is located between the pair of bullet terminals, and is electrically connected to the RAU through at least one circuit board for transmitting signals to and from the RAU. When the at least one pluggable remote actuator module is docked with the power-distribution-device base along the first direction, the pair of bullet terminals are inserted into the pair of bullet slots on the power-distribution-device base and allow power connection, and the BMI male terminal is inserted into the BMI female terminal on the power-distribution-device base and allows signal connection.

In an embodiment, the electronic device is a communication power supply device.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural perspective view illustrating a pluggable remote actuator module and a power-distribution-device base according to a first embodiment of the present disclosure;

FIG. 2 is a structural perspective view illustrating the pluggable remote actuator module and the power-distribution-device base according to the first embodiment of the present disclosure and taken from another perspective;

FIG. 3 is a schematic diagram showing the pluggable remote actuator module and the power-distribution-device base detached from each other according to the first embodiment of the present disclosure;

FIG. 4 is a schematic diagram showing the pluggable remote actuator module and the power-distribution-device base docked with each other according to the first embodiment of the present disclosure;

FIG. 5 is a structural perspective view illustrating the pluggable remote actuator module according to the first embodiment of the present disclosure;

FIG. 6 is a schematic exploded view illustrating the pluggable remote actuator module according to the first embodiment of the present disclosure;

FIG. 7 is a structural perspective view illustrating a pluggable remote actuator module according to a second embodiment of the present disclosure;

FIG. 8 is a schematic exploded view illustrating the pluggable remote actuator module according to the second embodiment of the present disclosure;

FIG. 9 is a structural perspective view illustrating a pluggable remote actuator module according to a third embodiment of the present disclosure; and

FIG. 10 is a schematic exploded view illustrating the pluggable remote actuator module according to the third embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “front,” “rear,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments.

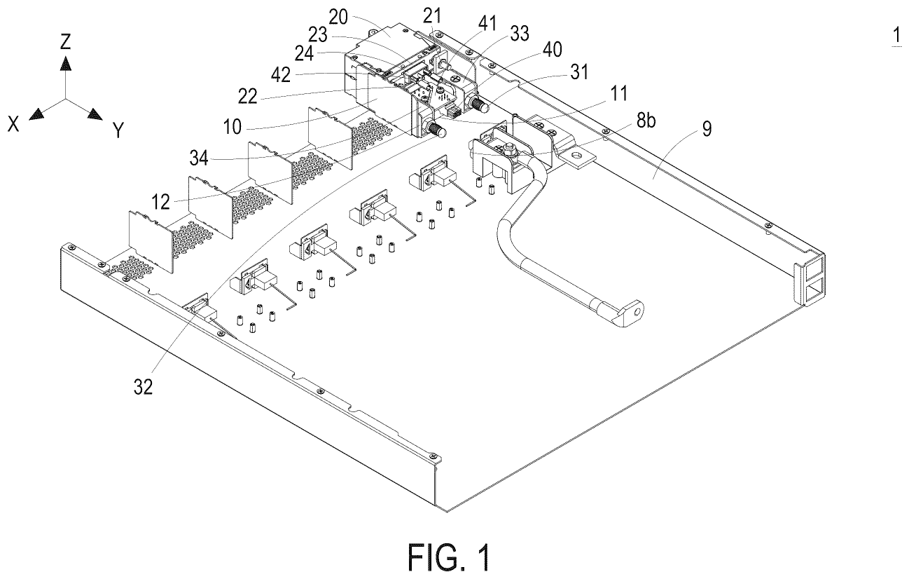

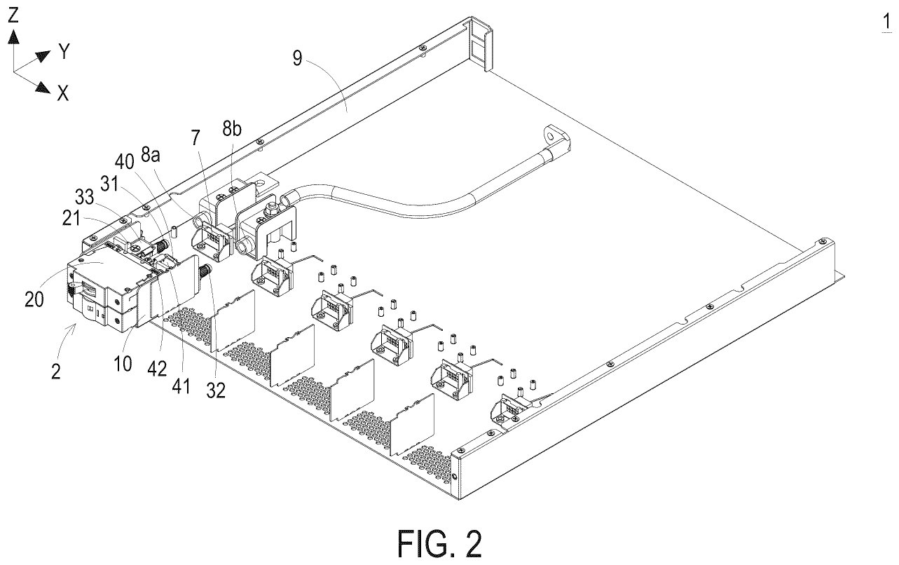

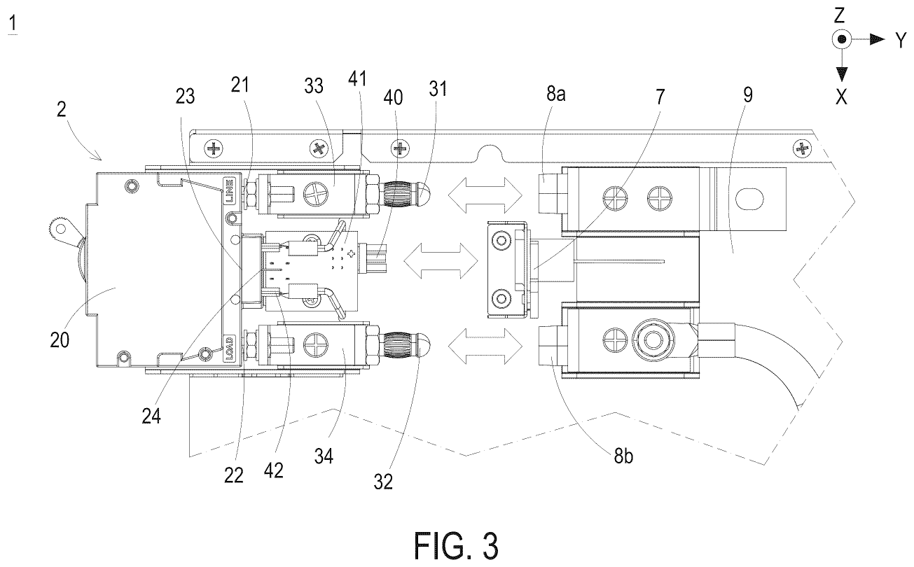

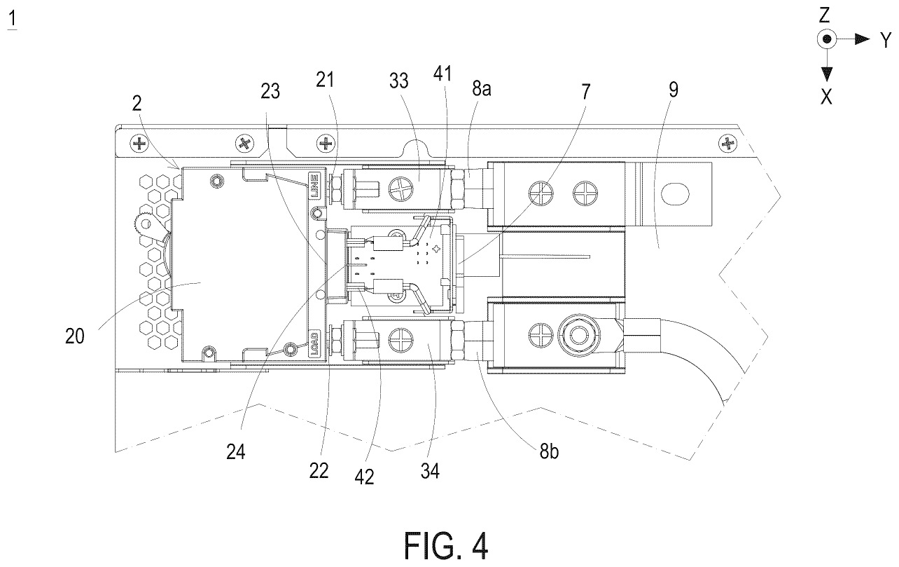

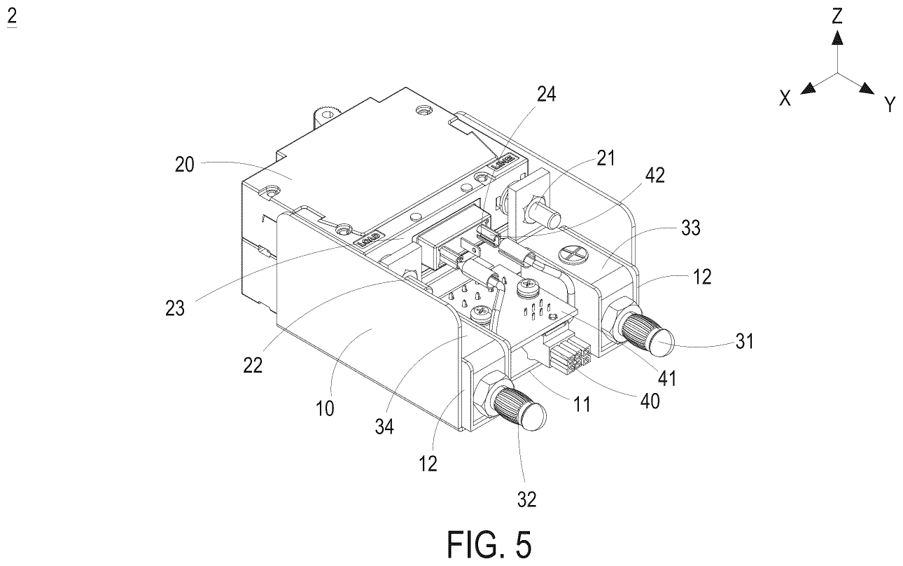

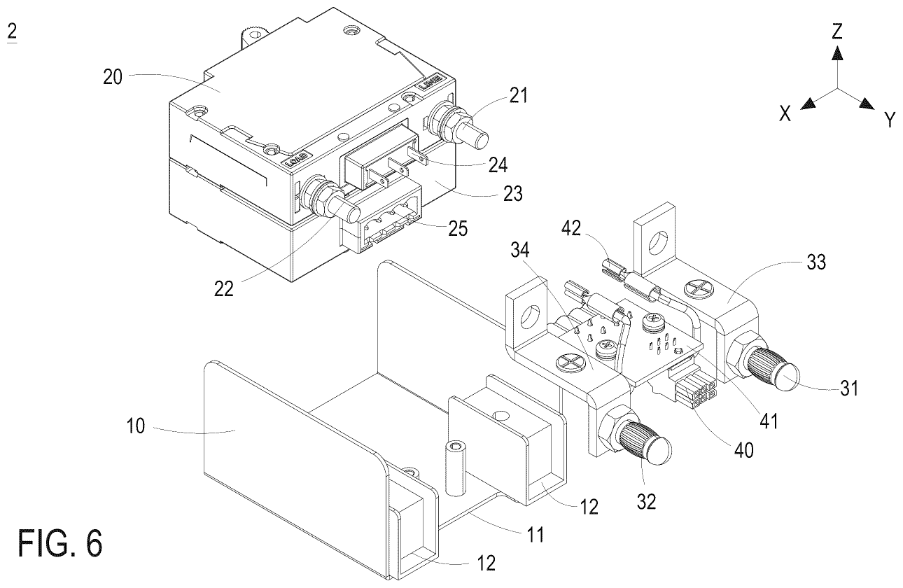

FIG. 1 is a structural perspective view illustrating a pluggable remote actuator module and a power-distribution-device base according to a first embodiment of the present disclosure. FIG. 2 is a structural perspective view illustrating the pluggable remote actuator module and the power-distribution-device base according to the first embodiment of the present disclosure and taken from another perspective. FIG. 3 is a schematic diagram showing the pluggable remote actuator module and the power-distribution-device base detached from each other according to the first embodiment of the present disclosure. FIG. 4 is a schematic diagram showing the pluggable remote actuator module and the power-distribution-device base docked with each other according to the first embodiment of the present disclosure. FIG. 5 is a structural perspective view illustrating the pluggable remote actuator module according to the first embodiment of the present disclosure. FIG. 6 is a schematic exploded view illustrating the pluggable remote actuator module according to the first embodiment of the present disclosure. Please refer to FIG. 1 to FIG. 6. The present disclosure provides an electronic device 1 including a power-distribution-device base 9 and at least one pluggable remote actuator module 2. Preferably but not exclusively, the electronic device 1 is a communication power supply device. The remote actuator module 2 is disposed on the power-distribution-device base 9 by means of plugging, so that the power of the electronic device 1 can be turned on or off remotely and the power of the electronic device 1 can be further monitored. In an embodiment, a plurality of pluggable remote actuator modules 2 are disposed on the power-distribution-device base 9 of the electronic device 1. Each remote actuator module 2 is independent of the power distribution device base 9, and can be independently inserted into or removed from the power-distribution-device base 9 without being affected. In the embodiment, only one single remote actuator module 2 is used to illustrate the docking relationship with the power-distribution-device base 9. The present disclosure is not limited thereto.

In the embodiment, the power-distribution-device base 9 includes a pair of bullet slots 8a, 8b and a blind mate interface (BMI) female terminal 7. The pair of bullet slots 8a, 8b and the BMI female terminal 7 are arranged to face an identical direction, such as the inverse Y axial direction, so as to connect with the pluggable remote actuator module 2 by means of docking. Preferably but not exclusively, the pair of bullet slots 8a, 8b includes a line bullet slot 8a and a load bullet slot 8b. Notably, the arrangement and installation of the bullet slots 8a, 8b and the BMI female terminal 7 are modularized. In other embodiments, the power-distribution-device base 9 includes a plurality of combinations of the bullet slots 8a, 8b and the BMI female terminal 7, and each combination of the bullet slots 8a, 8b and the BMI female terminal 7 has the same size configuration and allows docking with the same modular remote actuator module 2. Certainly, the present disclosure is not limited thereto.

In the embodiment, the at least one pluggable remote actuator module 2 includes a base 10, a remote actuator unit (RAU) 20, a pair of bullet terminals 31, 32 and a BMI male terminal 40. The RAU 20 is disposed on the base 10. Preferably but not exclusively, in the embodiment, the pair of bullet terminals 31, 32 includes a line bullet terminal 31 and a load bullet terminal 32, which are disposed adjacent to two opposite ends of a front edge 11 of the base 10. The line bullet terminal 31 and the load bullet terminal 32 face a first direction (i.e., the Y axial direction), and are electrically connected to the RAU 20 for transmitting power to and from the RAU 20. In addition, the BMI male terminal 40 is disposed adjacent to the front edge 11 of the base 10, and faces the first direction (i.e., the Y axial direction). The BMI male terminal 40 is located between the pair of bullet terminals 31, 32, and electrically connected to the RAU 20 through at least one circuit board for transmitting signals to and from the RAU 20. In the embodiment, the line bullet terminal 31, the loaded bullet terminal 32 and the BMI male terminal 40 are arranged and installed relative to the line bullet slot 8a, the load bullet slot 8b and the BMI female terminal 7 on the power-distribution-device base 9 in a modular design, so that it allows to dock the remote actuator module 2 and the power-distribution-device base 9 by means of plugging.

In the embodiment, when the at least one pluggable remote actuator module 2 is docked with the power-distribution-device base along the first direction (i.e., the Y axial direction), the line bullet terminal 31 and the load bullet terminal 32 facing the first direction are inserted into the line bullet slot 8a and the load bullet slot 8b on the power-distribution-device base 9, respectively, and allow power connection through the remote actuator module 2. At the same time, the BMI male terminal 40 facing the first direction on the remote actuator module 2 is inserted into the BMI female terminal 7 on the power-distribution-device base 9 and allows signal connection through the remote actuator module 2. Certainly, the remote actuator module 2 can be detached from the power-distribution-device base 9 along the reverse direction of the first direction. In other words, the line bullet terminal 31, the load bullet terminal 32 and the BMIN male terminal 40 on the remote actuator module 2 of the present disclosure can enter/leave the power-distribution-device base 9 at the same time, and the connection/disconnection of power and signal is achieved at the same time during the process of plugging/unplugging the remote actuator module 2. The connection between the pluggable remote actuator module 2 and the electronic-device base 9 is realized through a modular design. The remote actuator module 2 can be directly hot-swapped and replaced during site maintenance, so that the operating procedures are simplified effectively and the work efficiency is improved.

In the embodiment, the RAU 20 includes a line end 21, a load end 22 and a front surface 23. The line end 21 and the load end 22 are disposed adjacent to an upper edge of the front surface 23. The line end 21 is connected to the line bullet terminal 31 through a line metal conductor 33, and the load end 22 is connected to the load bullet terminal 32 through a load metal conductor 34. Moreover, in the embodiment, the pluggable remote actuator module 2 further includes a pair of fixtures 12. The pair of fixtures 12 are disposed adjacent to two opposite ends of the front edge 11 of the base 10, respectively, and connected between the front surface 23 of the RAU 20 and the front edge 11 of the base 10. Preferably but not exclusively, the pair of fixtures 12 are made of an insulating material, and configured to support the line metal conductor 33 and the load metal conductor 34, and fix the line bullet terminal 31 and the load bullet terminal 32. In the embodiment, the line metal conductor 33 and the load metal conductor 34 are formed by bending metal plates. The line metal conductor 33 and the load metal conductor 34 are fastened on top surfaces of the pair of fixtures 12 through screws, and the line bullet terminal 31 and the load bullet terminal 32 are fixed on front ends of the pair of fixtures 12. Thereby, the front end of the line bullet terminal 31 and the front end of the loaded bullet terminal 32 are protruded from the front edge 11 of the base 10 along the first direction (i.e., the Y axial direction), so as to facilitate dock with the line bullet slot 8a and the load bullet slot 8b on the power-distribution-device base 9. Certainly, the present disclosure is not limited thereto.

On the other hand, in the embodiment, the connection between the RAU 20 and the BMI male terminal 40 is integrated through at least one circuit board. The at least one circuit board is an integrated circuit board 41, which is fastened on the base 10, located between the pair of fixtures 12, and connected between the BMI male terminal 40 and the front surface 23 of the RAU 20. In the embodiment, the RAU 20 further includes a signal terminal 25. The signal terminal 25 is disposed adjacent to a lower edge of the front surface 23, spatially corresponding to the integrated circuit board 41 and directly connected to the integrated circuit board 40. Moreover, in the embodiment, the RAU 20 further includes an auxiliary contact 24. The auxiliary contact 24 is disposed adjacent to the upper edge of the front surface 23 and located between the line end 21 and the load end 22. In the embodiment, the pluggable remote actuator module 2 further includes a crimp terminal 42. In the embodiment, the auxiliary contact 24 located adjacent to the upper edge of the front surface 23 is connected to the integrated circuit board 41 corresponding to the lower edge of the front surface through the crimp terminal 42. Thereby, the auxiliary contact 24 and the signal terminal 25 of the RAU 20 are integrated into the BMI male terminal 40 through the integrated circuit board 41. It helps to increase the reliability of the communication connection when the remote actuator module 2 is connected in the blindly plugging way. Furthermore, the BMI male terminal 40 is arranged correspondingly between the line bullet terminal 31 and the load bullet terminal 32, and corresponds to the line bullet slot 8a, the load bullet slot 8b and the BMI female terminal 7 on the electronic-device base 9 to form an optimal alignment mechanism. Thereby, the docking process is simplified and the sufficient structural support is provided to prevent the bullet terminals and the BMI terminals from being damaged during the plugging/unplugging process of the remote actuator module 2. Certainly, the present disclosure is not limited thereto.

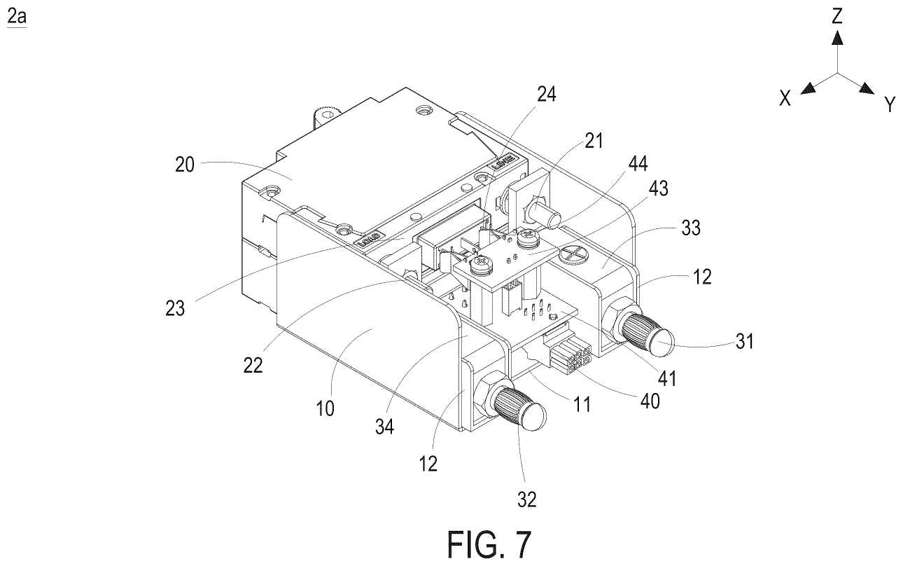

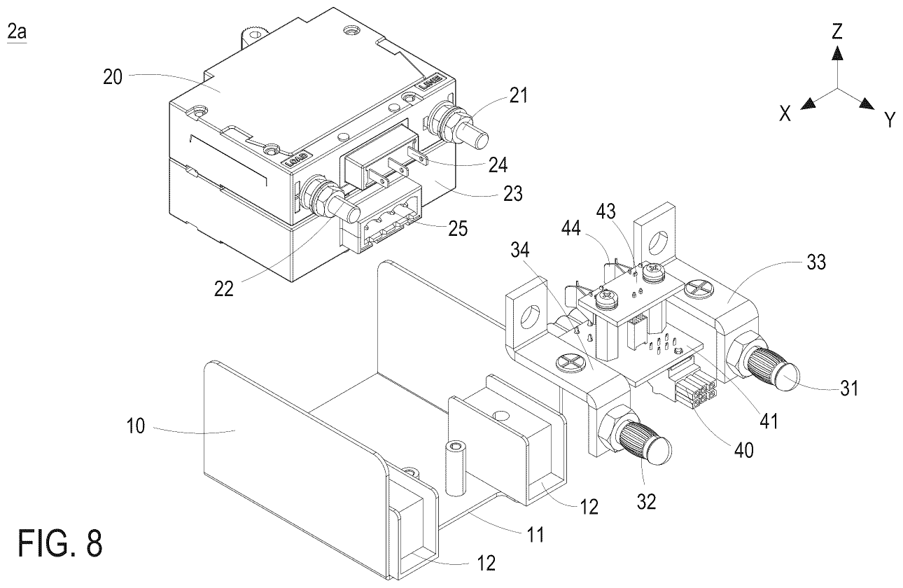

FIG. 7 is a structural perspective view illustrating a pluggable remote actuator module according to a second embodiment of the present disclosure. FIG. 8 is a schematic exploded view illustrating the pluggable remote actuator module according to the second embodiment of the present disclosure. In the embodiment, the structures, elements and functions of the pluggable remote actuator module 2a are similar to those of the pluggable remote actuator module 2 in FIG. 1 to FIG. 6, and are not redundantly described herein. Please refer to FIG. 2, FIG. 7 and FIG. 8. In the embodiment, the pluggable remote actuator module 2a further includes an auxiliary circuit board 43 and a clip component 44. The auxiliary circuit board 43 is spatially corresponding to the auxiliary contact 24 arranged adjacent to the upper edge of the front surface 23 of the RAU 20. The integrated circuit board 41 is spatially corresponding to the signal terminal 25 arranged adjacent to the lower edge of the front surface 23 of the RAU 20, and the integrated circuit board 41 is directly connected between the signal terminal 25 and the BMI male terminal 40. Preferably but not exclusively, the auxiliary circuit board 43 is disposed in parallel on the integrated circuit board 41 through support pillars. Moreover, the auxiliary circuit board 43 and the integrated circuit board 41 are electrically connected to each other through conductive pins. In the embodiment, the clip component 44 is arranged on a rear edge of the auxiliary circuit board 43, spatially corresponding to the auxiliary contact 24 of the RAU 20, and configured to clamp the auxiliary contact 24 to form an electrical connection. In this way, the auxiliary contact 24 and the signal terminal 25 of the RAU 20 are integrated into the BMI male terminal 40 through the integrated circuit board 41. It helps to increase the reliability of the communication connection when the remote actuator module 2a is connected in the blindly plugging way. Furthermore, the BMI male terminal 40 is arranged correspondingly between the line bullet terminal 31 and the load bullet terminal 32, and corresponds to the line bullet slot 8a, the load bullet slot 8b and the BMI female terminal 7 on the electronic-device base 9 to form an optimal alignment mechanism. Thereby, the docking process is simplified and the sufficient structural support is provided to prevent the bullet terminals and the BMI terminals from being damaged during the plugging/unplugging process of the remote actuator module 2. Certainly, the present disclosure is not limited thereto.

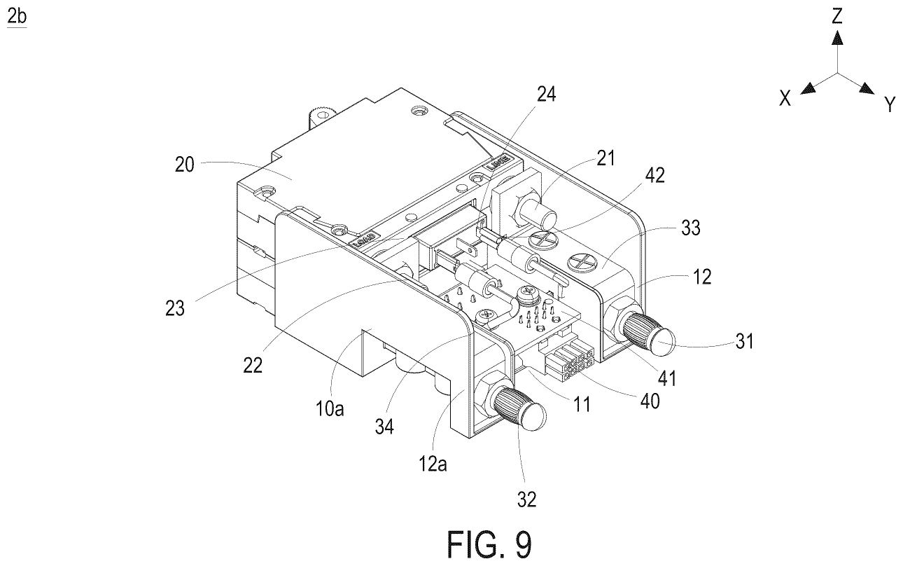

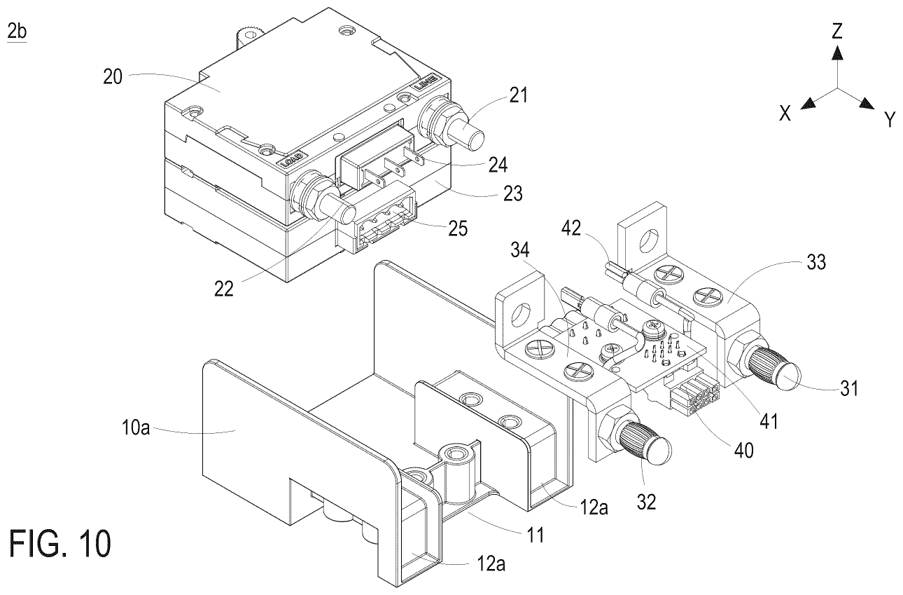

FIG. 9 is a structural perspective view illustrating a pluggable remote actuator module according to a third embodiment of the present disclosure. FIG. 10 is a schematic exploded view illustrating the pluggable remote actuator module according to the third embodiment of the present disclosure. In the embodiment, the structures, elements and functions of the pluggable remote actuator module 2b are similar to those of the pluggable remote actuator module 2 in FIG. 1 to FIG. 6, and are not redundantly described herein. Please refer to FIG. 2, FIG. 9 and FIG. 10. In the embodiment, the RAU 20, the line bullet terminal 31, the load bullet terminal 32, the integrated circuit board 41 and the BMI male terminal 40 of the pluggable remote actuator module 2b are carried on the base 10a. In addition, the fixtures 12a configured to support the line metal conductor 33 and the load metal conductor 34 are disposed adjacent to the inner walls of the two opposite ends of the front edge 11 of the base 10a. Preferably but not exclusively, the integrated circuit board 41 is directly fixed between the two fixtures 12a. Preferably but not exclusively, in the embodiment, the base 10a and the pair of fixtures 12a are made of plastic materials and integrally formed into one piece. Thereby, the RAU 20, the line bullet terminal 31, the load bullet terminal 32, the line metal conductor 33, the load metal conductor 34, the integrated circuit board 41 and the BMI male terminal 40 can be easily assembled to the modular structure formed by the base 10a and the fixtures 12a. At the same time, in the modular structure, the BMI male terminal 40 is correspondingly arranged between the line bullet terminal 31 and the load bullet terminal 32 disposed in pair, which helps to correspond to the line bullet slot 8a, the load bullet slot 8b and the BMI female terminal 7 on the power-distribution-device base 9 (Referring to FIG. 2) to form an optimal alignment mechanism. Thereby, the docking process is simplified and the sufficient structural support is provided to prevent the bullet terminals and the BMI terminals from being damaged during the plugging/unplugging process of the remote actuator module 2a. Certainly, the present disclosure is not limited thereto.

In addition, it should be noted that in the foregoing embodiments, the power-distribution-device base 9 can be provided with a plurality of modular combinations of the bullet slots 8a, 8b and the BMI female terminal 7. Each combination of the bullet slots 8a, 8b and the BMI female terminal 7 has the identical-size configuration, and allows docking with the same modularized remote actuator modules 2, 2a, 2b. In other words, the line bullet terminal 31, the load bullet terminal 32 and the BMI male terminal 40 protruded form the front edges 11 in the remote actuator modules 2, 2a 2b have the identical-size configuration, corresponding to the modular combination of the bullet slots 8a, 8b and the BMI female terminal 7. In the modular manner of the present disclosure, it allows to simultaneously install a plurality of remote actuator modules 2, 2a, 2b on the power-distribution-device base 9 of a communication power supply device, and each remote actuator module can be taken out from the power-distribution-device base 9 and replaced individually. The process of inserting or removing each remote actuator module into the power-distribution-device base 9 requires only one plug/unplug action to complete the connection/disconnection of power and signals, so that the operating procedures are simplified effectively and the work efficiency is improved. Certainly, the configuration of the plurality of remote actuator modules 2, 2a, 2b on the power-distribution-device base 9 is adjustable according to the practical requirements. The present disclosure is not limited thereto and not redundantly described hereafter.

In summary, the present disclosure provides a pluggable remote actuator module and an electronic device using the same. An electronic-device base includes a bullet slot for power transmission and a BMI female terminal for communication transmission. In addition, the remote actuator module includes a bullet terminal and a BMI male terminal capable of entering/leaving the electronic-device base at the same time, so that the connection/disconnection of power and signal is achieved at the same time during the process of plugging/unplugging the remote actuator module. The connection between the pluggable remote actuator module and the electronic-device base is realized through a modular design. The remote actuator module can be directly hot-swapped and replaced during site maintenance. In the present disclosure, the line bullet terminal and the load bullet terminal constructed corresponding to the line end and the load end of the remote actuator unit are protruded from a front edge of the base along the docking direction to facilitate docking with the bullet slot on the electronic device base. The line end and the load end are extended to the bullet terminals through metal conductors. The metal conductors can be fixed by insulated fixtures on the base, so as to provide the sufficient structural support at the same time. The fixtures and the base can also be integrally formed from plastic materials. Furthermore, the auxiliary contacts and the signal terminals of the remote actuator unit are integrated into a BMI male terminal through a circuit board, and it helps to increase the reliability of the communication connection when the remote actuator module is connected in the blindly plugging way. Preferably, the auxiliary contacts and the signal terminals are assembled to an integrated circuit board through crimp terminals, auxiliary circuits or clip components, or directly connected the integrated circuit board, and then connected to the BMI male terminal. In this way, the BMI male terminal can be arranged correspondingly between the pairs of bullet terminals, and corresponds to the bullet slots and the BMI female terminal on the electronic-device base to form an optimal alignment mechanism. Thereby, the docking process is simplified and the sufficient structural support is provided to prevent the bullet terminals and BMI terminals from being damaged during the plugging/unplugging process of the remote actuator module. On the other hand, in the modular manner of the present disclosure, it allows to simultaneously install a plurality of remote actuator modules on the base of a communication power supply device, and each remote actuator module can be taken out and replaced individually. The process of inserting or removing each remote actuator module into the electronic-device base requires only one plug/unplug action to complete the connection/disconnection of power and signals, so that the operating procedures are simplified effectively and the work efficiency is improved. The present disclosure includes the industrial applicability and the inventive steps.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A pluggable remote actuator module comprising:
a base;
a remote actuator unit (RAU) disposed on the base;
a pair of bullet terminals disposed adjacent to a front edge of the base, facing a first direction, and electrically connected to the RAU for transmitting power to and from the RAU; and
a blind mate interface (BMI) male terminal disposed adjacent to the front edge of the base, facing the first direction, located between the pair of bullet terminals, and electrically connected to the RAU through at least one circuit board for transmitting signals to and from the RAU;
wherein when the pluggable remote actuator module is docked with a power-distribution-device base along the first direction, the pair of bullet terminals are inserted into a pair of bullet slots on the power-distribution-device base and allow power connection, and the BMI male terminal is inserted into a BMI female terminal on the power-distribution-device base and allows signal connection.

2. The pluggable remote actuator module according to claim 1, wherein the pair of bullet terminals includes a line bullet terminal and a load bullet terminal, which are protruded from the front edge of the base along the first direction.

3. The pluggable remote actuator module according to claim 2, wherein the RAU comprises a line end, a load end and a front surface, the line end and the load end are disposed adjacent to an upper edge of the front surface, the line end is connected to the line bullet terminal through a line metal conductor, and the load end is connected to the load bullet terminal through a load metal conductor.

4. The pluggable remote actuator module according to claim 3, further comprising a pair of fixtures, wherein the pair of fixtures are disposed adjacent to two opposite ends of the front edge of the base, respectively, and connected between the front surface of the RAU and the front edge of the base, wherein the pair of fixtures are made of an insulating material, and configured to support the line metal conductor and the load metal conductor, and fix the line bullet terminal and the load bullet terminal.

5. The pluggable remote actuator module according to claim 4, wherein the line metal conductor and the load metal conductor are fastened on top surfaces of the pair of fixtures through screws, and the line bullet terminal and the load bullet terminal are fixed on front ends of the pair of fixtures.

6. The pluggable remote actuator module according to claim 4, wherein the base and the pair of fixtures are made of plastic materials and integrally formed into one piece.

7. The pluggable remote actuator module according to claim 4, wherein the at least one circuit board is an integrated circuit board fastened on the base, located between the pair of fixtures, and connected between the BMI male terminal and the front surface of the RAU.

8. The pluggable remote actuator module according to claim 7, wherein the RAU comprises a signal terminal disposed adjacent to a lower edge of the front surface, spatially corresponding to the integrated circuit board and directly connected to the integrated circuit board.

9. The pluggable remote actuator module according to claim 7, wherein the RAU comprises an auxiliary contact disposed adjacent to the upper edge of the front surface and located between the line end and the load end.

10. The pluggable remote actuator module according to claim 9, further comprising a crimp terminal, wherein the auxiliary contact is connected to the integrated circuit board through the crimp terminal.

11. The pluggable remote actuator module according to claim 9, further comprising an auxiliary circuit board and a clip component, wherein the auxiliary circuit board and the integrated circuit board are arranged in parallel and electrically connected to each other, and the clip component is arranged on an edge of the auxiliary circuit board, spatially corresponding to the auxiliary contact, and configured to clamp the auxiliary contact to form an electrical connection.

12. An electronic device comprising:
a power-distribution-device base comprising a pair of bullet slots and a blind mate interface (BMI) female terminal, wherein the pair of bullet slots and the BMI female terminal are arranged to face an identical direction; and
at least one pluggable remote actuator module, comprising:
a base;
a remote actuator unit (RAU) disposed on the base;
a pair of bullet terminals disposed adjacent to a front edge of the base, facing a first direction, and electrically connected to the RAU for transmitting power to and from the RAU; and
a BMI male terminal disposed adjacent to the front edge of the base, facing the first direction, located between the pair of bullet terminals, and electrically connected to the RAU through at least one circuit board for transmitting signals to and from the RAU;
wherein when the at least one pluggable remote actuator module is docked with the power-distribution-device base along the first direction, the pair of bullet terminals are inserted into the pair of bullet slots on the power-distribution-device base and allow power connection, and the BMI male terminal is inserted into the BMI female terminal on the power-distribution-device base and allows signal connection.

13. The electronic device according to claim 12, wherein the electronic device is a communication power supply device.
